(19) United States
(12) Patent Application Publication
(10) Pub. No.: US 2013/0015936 A1
(43) Pub. Date: Jan. 17, 2013

(54) CONVERTER AND METHOD FOR MANUFACTURING THE SAME

(71) Applicant: Quansong Luo, Shanghai (CN)

(72) Inventor: Quansong Luo, Shanghai (CN)

(73) Assignee: DELTA ELECTRONICS (SHANGHAI) CO., LTD., Shanghai (CN)

(21) Appl. No.: 13/495,459

(22) Filed: Jun. 13, 2012

Related U.S. Application Data
(60) Provisional application No. 61/507,801, filed on Jul. 14, 2011.

(51) Int. Cl. H01F 5/00; H05K 3/36

(52) U.S. Cl. 336/200; 29/830

(57) ABSTRACT

A converter includes a main board, at least one first connecting member, and a magnetic component. The first connecting member is defined on a surface of the main board. The magnetic component is assembled with the main board. The magnetic component includes a winding board, at least one second connecting member and a core. The second connecting member is defined on a surface of the winding board, and the second connecting member is in electrical contact with the first connecting member. The core is assembled with the winding board. A method for manufacturing a converter is also disclosed herein.

### RELATED APPLICATIONS

This application claims priority to U.S. provisional Application Ser. No. 61/507,801, filed Jul. 14, 2011, which is herein incorporated by reference in its entirety.

### BACKGROUND

1. Technical Field

The present disclosure relates to a converter. More particularly, the present disclosure relates to a configuration of a converter.

2. Description of Related Art

A converter, like a DC-DC converter, is required in various electronic devices (for example, digital cameras, personal computers, audio/video players, and personal digital assistant), for converting power voltages to operation voltages provided for elements or circuits in the electronic devices. A conventional converter typically includes a printed circuit board (PCB) having through holes and a transformer having terminals that are in the form of legs, and the legs of the transformer are inserted into the through holes of the PCB, such that the transformer is assembled to the PCB.

However, since the PCB has to be formed with the through holes and the transformer also has to be formed with the legs inserted into the through holes so that the transformer can be assembled to the PCB during the manufacturing process, the manufacturing process is inconvenient and complicated, and thus the cost of manufacturing the converter is still high and cannot be reduced.

### SUMMARY

An aspect of the present disclosure is related to a converter. The converter includes a main board, at least one first connecting member, and a magnetic component. The first connecting member is defined on a surface of the main board. The magnetic component is configured to be assembled with the main board. The magnetic component includes a winding board, at least one second connecting member and a core. The second connecting member is defined on a surface of the winding board, and the second connecting member is configured to be in electrical contact with the first connecting member. The core is configured to be assembled with the winding board.

Another aspect of the present disclosure is related to a converter. The converter includes a converter circuit board, a plurality of first pads, a winding board, a plurality of second pads and a core. The first pads are formed on a surface of the converter circuit board. The winding board includes a first hollow portion. The second pads are formed on a surface of the winding board, and the second pads are configured to be soldered to the first pads, respectively. The core are configured to pass through the first hollow portion of the winding board.

Still another aspect of the present disclosure is related to a method for manufacturing a converter including a main board, a winding board and a core. The method includes the steps describer below. A plurality of first pads are formed on a surface of the main board. A plurality of second pads are formed on a surface of the winding board. The winding board is assembled to the main board, and the second pads are soldered to the first pads, respectively. The core is assembled to the winding board and the main board.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiments, with reference to the accompanying drawings as follows:

FIG. 1 is a schematic diagram of a side view of a converter according to one embodiment of the present disclosure;

FIG. 2 is a diagram illustrating the winding board shown in FIG. 1 according to one embodiment of the present disclosure;

FIG. 3 is a diagram illustrating the main board shown in FIG. 1 according to one embodiment of the present disclosure;

FIG. 4 is a schematic diagram of a side view of a converter according to another embodiment of the present disclosure;

FIG. 5 is a diagram illustrating the winding board shown in FIG. 4 according to one embodiment of the present disclosure;

FIG. 6 is a diagram illustrating the main board shown in FIG. 4 according to one embodiment of the present disclosure;

FIG. 7 is a schematic diagram illustrating configurations of the main board and the winding board according to one embodiment of the present disclosure;

FIG. 8 is a schematic diagram illustrating configurations of the main board and the winding board according to another embodiment of the present disclosure;

FIG. 9 is a schematic diagram illustrating configurations of the main board and the winding board according to still another embodiment of the present disclosure; and

FIG. 10 is a flow chart of a method for manufacturing a converter according to one embodiment of the present disclosure, and the method is described below.

### DESCRIPTION OF THE EMBODIMENTS

In the following description, specific details are presented to provide a thorough understanding of the embodiments of the present disclosure. Persons of ordinary skill in the art will recognize, however, that the present disclosure can be practiced without one or more of the specific details, or in combination with other components. Well-known implementations or operations are not shown or described in detail to avoid obscuring aspects of various embodiments of the present disclosure.

The terms used in this specification generally have their ordinary meanings in the art and in the specific context where each term is used. The use of examples anywhere in this specification, including examples of any terms discussed herein, is illustrative only, and in no way limits the scope and meaning of the disclosure or of any exemplified term. Likewise, the present disclosure is not limited to various embodiments given in this specification.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

As used herein, the terms “comprising,” “including,” “having,” “containing,” “involving,” and the like are to be understood to be open-ended, i.e., to mean including but not limited to.

Reference throughout the specification to “one embodiment” or “an embodiment” means that a particular feature, structure, implementation, or characteristic described in connection with the embodiment is included in at least one embodiment of the present disclosure. Therefore, uses of the phrases “in one embodiment” or “in an embodiment” in various places throughout the specification are not necessarily all referring to the same embodiment. Furthermore, the particular features, structures, implementation, or characteristics may be combined in any suitable manner in one or more embodiments.

In the following description and claims, the terms “coupled” and “connected”, along with their derivatives, may be used. In particular embodiments, “connected” and “coupled” may be used to indicate that two or more elements are in direct physical or electrical contact with each other, or may also mean that two or more elements may not be in direct contact with each other. “Coupled” may still be used to indicate that two or more elements cooperate or interact with each other.

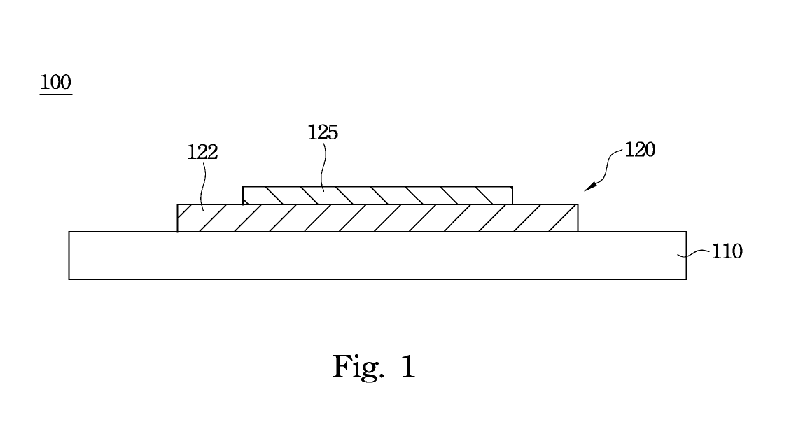

FIG. 1 shows a schematic diagram of a side view of a converter according to one embodiment of the present disclosure. As shown in FIG. 1, the converter 100, e.g., a DC/DC converter or the other type of converter, includes a main board 110 and a magnetic component 120 configured to be assembled with the main board 110, in which the magnetic component 120 includes a winding board 122 and a core 125 configured to be assembled with the winding board 122. However, other well-known components are not shown or described in detail in FIG. 1 in order to avoid obscuring features and aspects of various embodiments of the present disclosure, and thus FIG. 1 is shown for schematic illustration and not limiting the present disclosure.

In one embodiment, the magnetic component 120 is a transformer, an inductor, or the other type of electromagnetic element, and the main board 110 is a converter circuit board. In another embodiment, the main board 110 is a converter printed circuit board (PCB), and the winding board 122 is a winding printed circuit board (PCB) (or named PCB winding). In practice, each of the main board 110 and the winding board 122 can be fabricated using well-known circuit lamination techniques in the art.

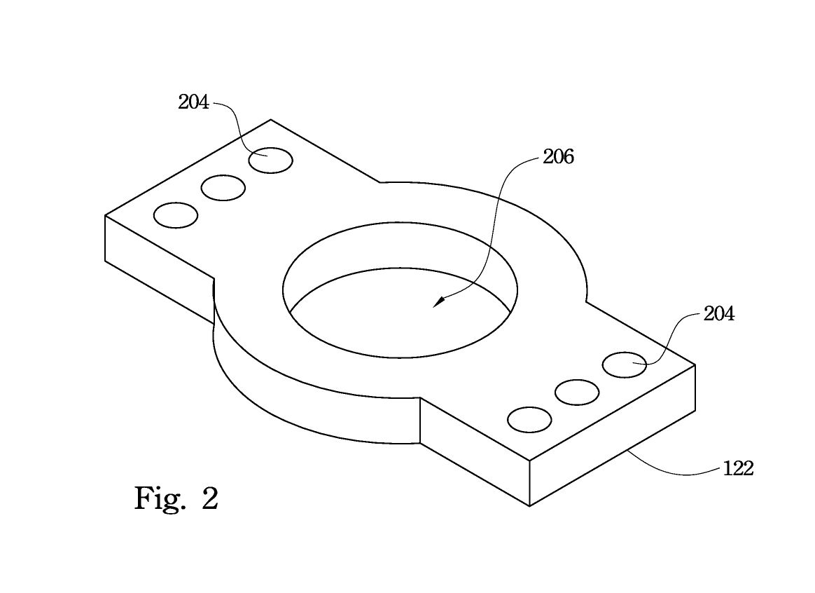

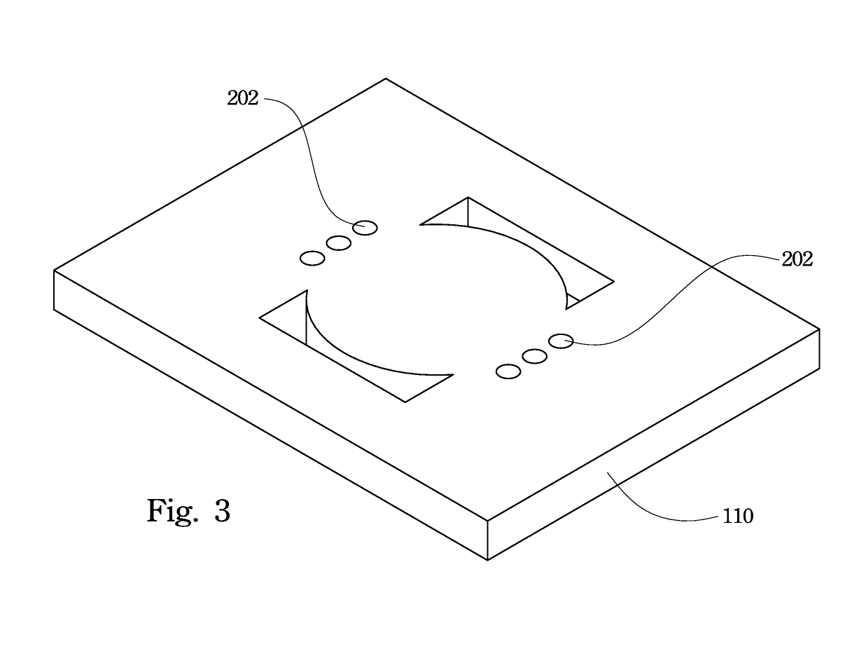

FIG. 2 is a diagram illustrating the winding board shown in FIG. 1 according to one embodiment of the present disclosure. FIG. 3 is a diagram illustrating the main board shown in FIG. 1 according to one embodiment of the present disclosure. Referring to FIGS. 1 to 3, the converter 100 further includes at least one first connecting member 202 and at least one second connecting member 204, in which the first connecting member 202 is defined on a surface of the main board 110, the second connecting member 204 is defined on a surface of the winding board 122, and the second connecting member 204 is configured to be in electrical contact with the first connecting member 202.

Specifically, the converter 100 may include a plurality of first connecting members 202 defined on the surface of the main board 110, and a plurality of second connecting members 204 defined on the surface of the winding board 122, and the winding board 122 can be electrically connected to the main board 110 by the second connecting members 204 being in electrical contact with the first connecting members 202, respectively, when the winding board 122 is assembled with the main board 110. In one embodiment, the second connecting members 204 are soldered to the first connecting members 202, respectively, for example by solder paste, when the winding board 122 is assembled with the main board 110.

In practice, the number of the first connecting members 202 and the number of the second connecting members 204 can be modified according to the type of the main board 110, the winding board 122, and/or the type of the converter 100; that is, persons of ordinary skill in the relevant art will recognize that the number of the first connecting members 202 and the second connecting members 204 can be modified according to practical needs, and thus the number of the first connecting members 202 and the second connecting members 204 shown in FIG. 2 and FIG. 3 are merely illustrative and not limiting of the present disclosure.

In one embodiment, the first connecting member 202 is formed from one or more conductive layers patterned on the surface of the main board 110, and the second connecting member 204 is formed from one or more conductive layers patterned on the surface of the winding board 122, such that the first connecting member 202 and the second connecting member 204 may be formed, for example, during a lamination manufacturing process for the main board 110 and the winding board 122.

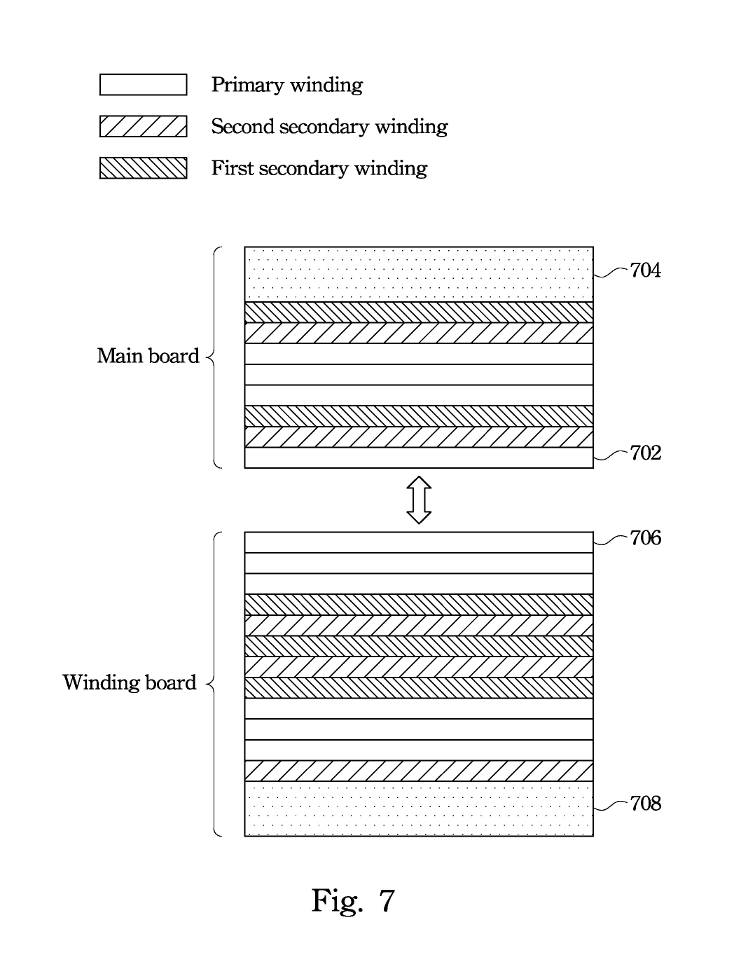

In another embodiment, the main board 110 may further include a plurality of conductive layers (as shown in FIG. 7), and the winding board 122 may further include a plurality of conductive layers (as shown in FIG. 7), in which the first connecting member 202 is formed from an outermost one (for example, the conductive layer 702 shown in FIG. 7) of the conductive layers of the main board 110, and the second connecting member 204 is formed from an outermost one (for example, the conductive layer 706 shown in FIG. 7) of the conductive layers of the winding board 122, such that the first connecting member 202 and the second connecting member 204 are formed, for example, during a lamination manufacturing process for the main board 110 and the winding board 122.

In the embodiments mentioned above, each of the first connecting member 202 and the second connecting member 204 can be a pad, e.g., a contact pad, a bond pad, and a soldering pad, which is made of one or more layers of conductive material such as copper (Cu), aluminum (Al), gold (Au), silver (Ag), tin (Sn), nickel (Ni), or the combination thereof. In the aforementioned embodiments, the pad can be implemented by a metal foil which is a copper foil, an aluminum foil, a gold foil, a silver foil, a tin foil, a nickel foil, or the combination thereof.

Furthermore, referring to FIGS. 1 to 3, the winding board 122, as an embodiment, may further include a first hollow portion 206, and the first hollow portion 206 is configured for the core 125 to pass through when the winding board 122 is assembled with the core 125.

In operation, the first connecting member 202 defined on the main board 110 and the second connecting member 204 defined on the winding board 122 are configured to have a same voltage; in other words, under the condition that the first connecting member 202 is formed from the outermost conductive layer of the main board 110 and the second connecting member 204 is formed from the outermost conductive layer of the winding board 122, the outermost conductive layer of the main board 110 and the outermost conductive layer of the winding board 122 are configured to have the same voltage.

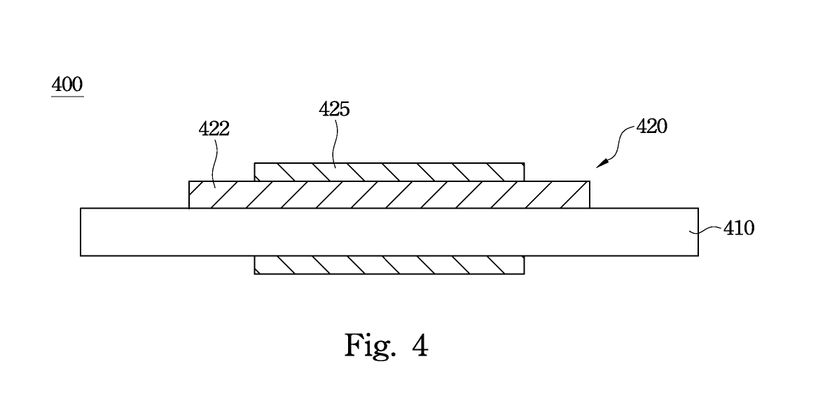

FIG. 4 is a schematic diagram of a side view of a converter according to another embodiment of the present disclosure. As shown in FIG. 4, the converter 400, e.g., a DC/DC converter or the other type of converter, includes a main board 410 and a magnetic component 420 configured to be assembled with the main board 410, in which the magnetic component 420 includes a winding board 422 and a core 425 configured to be assembled with the winding board 122 and the main board 410. Similarly, other well-known components are not shown or described in detail in FIG. 4 in order to avoid obscuring features and aspects of various embodiments of the present disclosure, and thus FIG. 4 is shown for schematic illustration and not for limiting the present disclosure.

The magnetic component 420 can be a transformer, an inductor, or the other type of electromagnetic element, and the main board 410 can be a converter circuit board, in which the main board 110 may be a converter printed circuit board (PCB), and the winding board 122 may be a winding printed circuit board (PCB) (or named PCB winding). In practice, each of the main board 410 and the winding board 422 can be fabricated using well-known circuit lamination techniques.

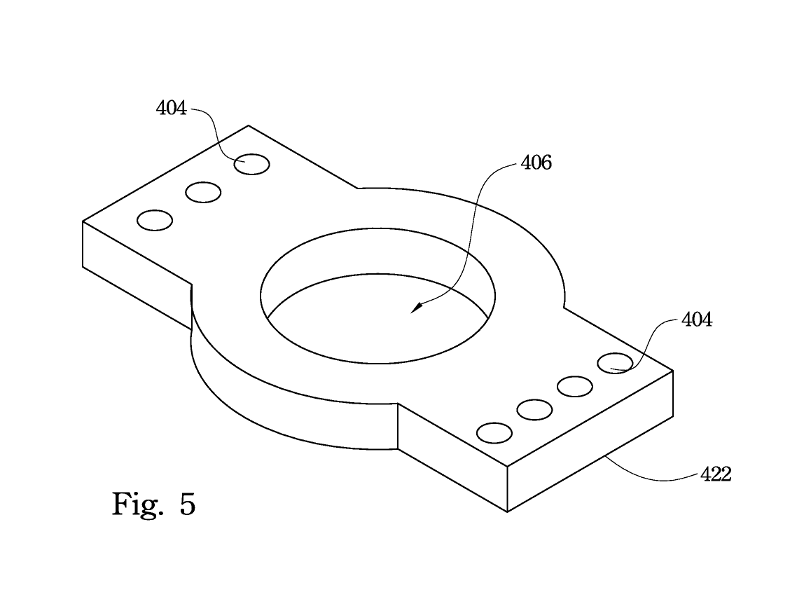

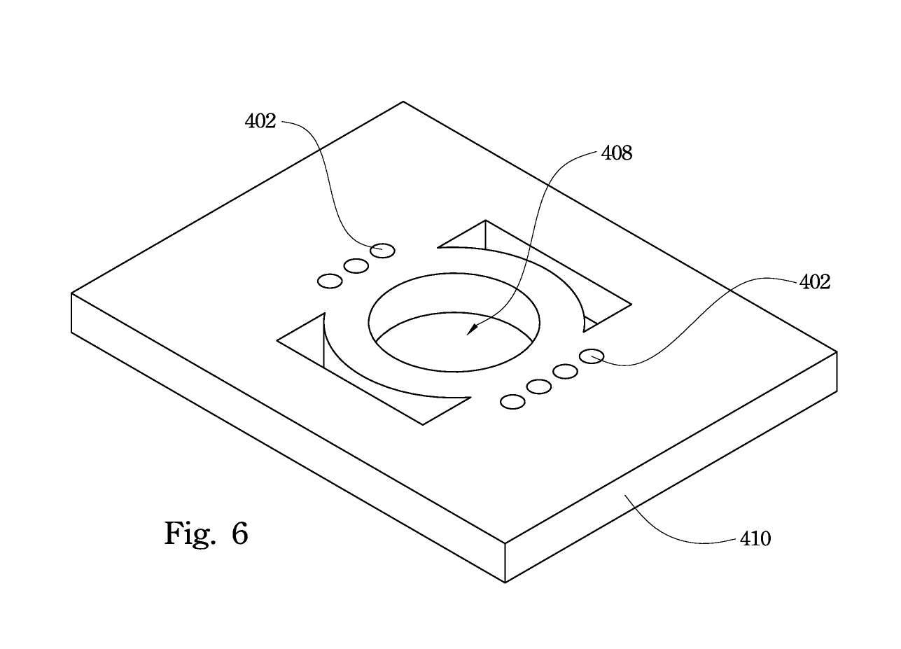

FIG. 5 is a diagram illustrating the winding board shown in FIG. 4 according to one embodiment of the present disclosure. FIG. 6 is a diagram illustrating the main board shown in FIG. 4 according to one embodiment of the present disclosure. Referring to FIGS. 4 to 6, the converter 400 further includes at least one first connecting member 402 and at least one second connecting member 404, in which the first connecting member 402 is defined on a surface of the main board 410, the second connecting member 404 is defined on a surface of the winding board 422, and the second connecting member 404 is configured to be in electrical contact with the first connecting member 402.

Specifically, as an embodiment, the converter 400 may include a plurality of first connecting members 402 defined on the surface of the main board 410, and a plurality of second connecting members 404 defined on the surface of the winding board 422, and the winding board 422 can be electrically connected to the main board 410 when the second connecting members 404 are soldered to the first connecting members 402, respectively, for example, by solder paste.

The number of the first connecting members 402 and the number of the second connecting members 404 can be modified according to the type of the main board 410, the winding board 422, and/or the type of the converter 400; in other words, persons of ordinary skill in the art will recognize that the number of the first connecting members 402 and the second connecting members 404 can be modified according to practical needs, and thus the number of the connecting members shown in FIG. 5 and FIG. 6 are merely illustrative and not limiting of the present disclosure.

Furthermore, referring to FIGS. 4 to 6, the winding board 422, as an embodiment, may further include a first hollow portion 406, and the main board 410 may further include a second hollow portion 408, in which the first hollow portion 406 and the second hollow portion 408 are configured for the core 425 to pass through when the winding board 422 and the main board 410 are assembled with the core 425.

In one embodiment, the first connecting member 402 is formed from one or more conductive layers patterned on the surface of the main board 410, and the second connecting member 404 is formed from one or more conductive layers patterned on the surface of the winding board 422, such that the first connecting member 402 and the second connecting member 404 is formed, for example, during a lamination manufacturing process for the main board 410 and the winding board 422.

In another embodiment, the main board 410 may further include a plurality of conductive layers (as shown in FIG. 7), and the winding board 422 may further include a plurality of conductive layers (as shown in FIG. 7), in which the first connecting member 402 is formed from an outermost one (for example, the conductive layer 702 shown in FIG. 7) of the conductive layers of the main board 410, and the second connecting member 404 is formed from an outermost one (for example, the conductive layer 706 shown in FIG. 7) of the conductive layers of the winding board 422, such that the first connecting member 402 and the second connecting member 404 is formed, for example, during a lamination manufacturing process for the main board 410 and the winding board 422.

In the embodiments mentioned above, each of the first connecting member 402 and the second connecting member 404 can be a pad, e.g., a contact pad, a bond pad, and a soldering pad, which is made of one or more layers of conductive material such as copper (Cu), aluminum (Al), gold (Au), silver (Ag), tin (Sn), nickel (Ni), or the combination thereof. In the embodiments mentioned above, the pad can be implemented by a metal foil which is a copper foil, an aluminum foil, a gold foil, a silver foil, a tin foil, a nickel foil, or the combination thereof.

In operation, the first connecting member 402 defined on the main board 410 and the second connecting member 404 defined on the winding board 122 are similarly configured to have a same voltage; in other words, under the condition that the first connecting member 402 is formed from the outermost conductive layer of the main board 410 and the second connecting member 404 is formed from the outermost conductive layer of the winding board 422, the outermost conductive layer of the main board 410 and the outermost conductive layer of the winding board 422 are configured to have the same voltage.

As mentioned above, since it is merely required for the main board 110 (or 410) and the winding board 122 (or 422) to have connecting members (e.g., pads) thereon, the main board 110 (or 410) and the winding board 122 (or 422) can be electrically connected with each other when the connecting members on both of the boards are in electrical contact with each other. As a result, the process of manufacturing through holes on one board and the process of manufacturing terminals that are in the form of legs to be inserted into the through holes, on the other board, can thus be omitted. Therefore, the process of manufacturing a converter would be more convenient and simpler, further reducing the cost of manufacturing the converter.

In addition, since the connecting members can be formed from conductive layers patterned on the surface of a multi-layer board (e.g., a printed circuit board), or from conductive layers of the multi-layer board, the connecting members (e.g., pads) on one board can be soldered to the connecting members (e.g., pads) on the other board by using the same reflow and automation processes used for one board to be mounted on the other board, thus resulting in that the process of assembling the two boards becomes even more convenient and simpler.

Moreover, in that the winding board is used as windings and can be fabricated using well-known circuit lamination techniques, the volume of the winding board is smaller than conventional windings, and the winding board is much simpler and more reliable than conventional windings.

On the other hand, in the embodiments mentioned above, under the condition that the main board 110 (or 410) further includes a plurality of conductive layers and the winding board 122 (or 422) further includes a plurality of conductive layers, each of the conductive layers of the main board 110 (or 410) and the winding board 122 (or 422) can be formed by at least one primary winding, at least one secondary winding, or the combination thereof. Exemplary embodiments are illustrated below, and they are merely shown for convenience of illustration and not limiting of the present disclosure.

FIG. 7 is a schematic diagram illustrating configurations of the main board and the winding board according to one embodiment of the present disclosure. As shown in FIG. 7, each of the main board and the winding board is formed from a multi-layer board including a plurality of conductive layers, in which the conductive layers are implemented by primary windings, first secondary windings and second secondary windings. In the present embodiment, the primary windings, the first secondary windings and the second secondary windings are formed in a stacked and interleaved relation with each other, as shown in FIG. 7.

Moreover, in the present embodiment, the main board includes an outermost conductive layer (e.g., the primary winding) 702, and the connecting members (e.g., the pads) can be formed from or formed on the outermost conductive layer 702, for example, in the same lamination manufacturing process for the main board. Furthermore, there is an additional metal foil (e.g., a copper foil) 704 soldered to another conductive layer of the main board, and the metal foil 704 may function like the windings.

Similarly, the winding board includes an outermost conductive layer (e.g., the primary winding) 706, and the connecting members (e.g., the pads) can be formed from or formed on the outermost conductive layer 706, for example, in the same lamination manufacturing process for the winding board. Furthermore, there is also an additional metal foil (e.g., a copper foil) 708 soldered to another conductive layer of the winding board, and the metal foil 708 may also function like the windings.

In operation, the conductive layer 702 of the main board and the conductive layer 706 of the winding board are configured to have the same voltage, and both of the conductive layer 702 and the conductive layer 706 are configured to be the primary windings or the secondary windings, in order to cooperate with each other.

As a result, when the configuration shown in FIG. 7 is applied in a converter, the parasitic inter-winding capacitance between the primary windings and secondary windings is thus smaller, the AC coefficient becomes smaller, and the power loss decreases as well.

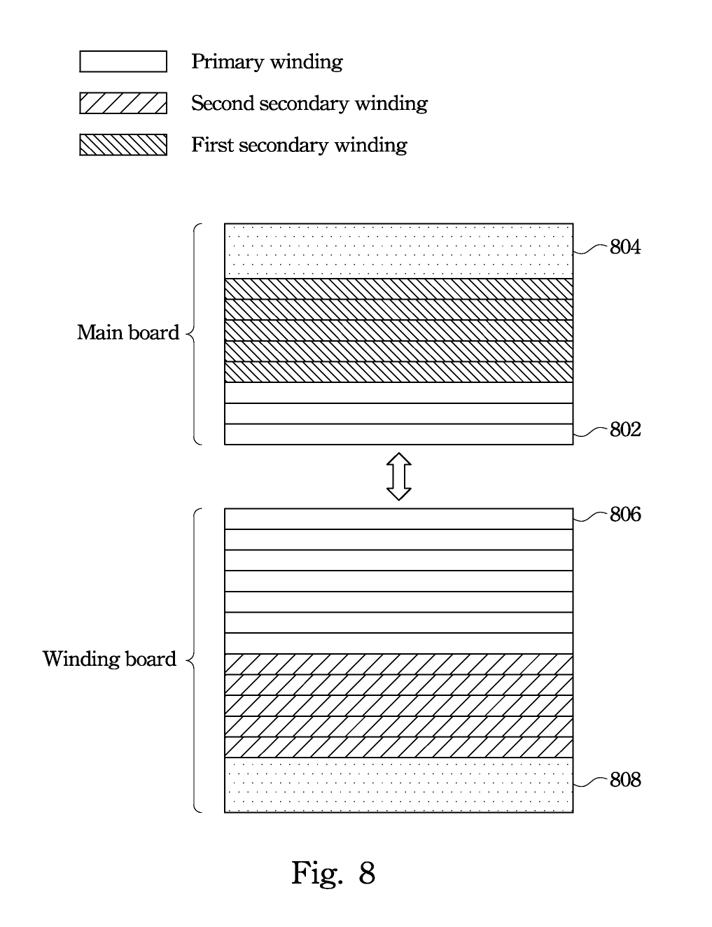

FIG. 8 is a schematic diagram illustrating configurations of the main board and the winding board according to another embodiment of the present disclosure. Compared to FIG. 7, the conductive layers of the main board are implemented by the primary windings and the first secondary windings, and the conductive layers of the winding board are implemented by the primary windings and the second secondary windings, as shown in FIG. 8. Similarly, the primary windings, the first secondary windings and the second secondary windings are formed in a stacked and interleaved relation with each other.

In the present embodiment, the main board includes an outermost conductive layer (e.g., the primary winding) 802, and the connecting members (e.g., the pads) can be formed from or formed on the outermost conductive layer 802, for example, in the same lamination manufacturing process for the main board. Furthermore, there is an additional metal foil (e.g., a copper foil) 804 soldered to another conductive layer of the main board, and the metal foil 804 may function like the windings.

Similarly, the winding board includes an outermost conductive layer (e.g., the primary winding) 806, and the connecting members (e.g., the pads) can be formed from or formed on the outermost conductive layer 806, for example, in the same lamination manufacturing process for the winding board. Furthermore, there is also an additional metal foil (e.g., a copper foil) 808 soldered to another conductive layer of the winding board, and the metal foil 808 may also function like the windings.

In operation, the conductive layer 802 of the main board and the conductive layer 806 of the winding board are configured to have the same voltage, and both of the conductive layer 802 and the conductive layer 806 are configured to be the primary windings or the secondary windings, in order to cooperate with each other.

As a result, when the configuration shown in FIG. 8 is applied in a converter, the parasitic inter-winding capacitance between the primary windings and secondary windings is smaller, and the electromagnetic interference (EMI), the ripples and the leakage inductance can thus be improved.

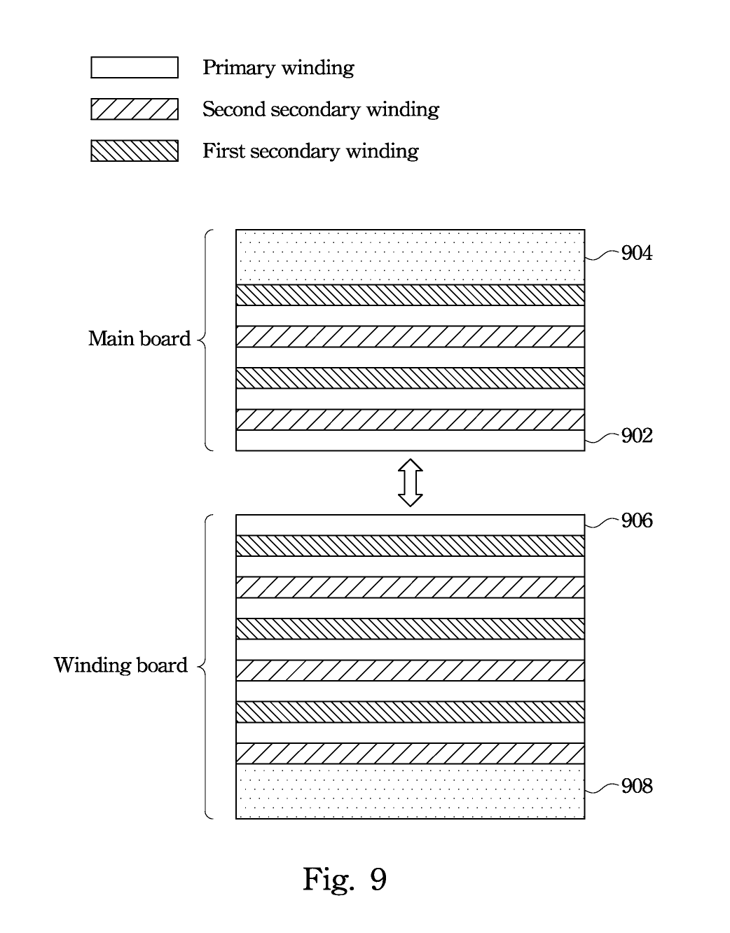

FIG. 9 is a schematic diagram illustrating configurations of the main board and the winding board according to still another embodiment of the present disclosure. Compared to FIG. 7, the conductive layers of the main board are implemented by the primary windings, the first secondary windings and the second secondary windings, which are formed in a stacked and more regular interleaved relation with each other, and the conductive layers of the main board are also implemented by the primary windings, the first secondary windings and the second secondary windings, which are formed in a stacked and more regular interleaved relation with each other, as shown in FIG. 9.

In the present embodiment, the main board includes an outermost conductive layer (e.g., the primary winding) 902, and the connecting members (e.g., the pads) can be formed from or formed on the outermost conductive layer 902, for example, in the same lamination manufacturing process for the main board. Furthermore, there is an additional metal foil (e.g., a copper foil) 904 soldered to another conductive layer of the main board, and the metal foil 904 may function like the windings.

Similarly, the winding board includes an outermost conductive layer (e.g., the primary winding) 906, and the connecting members (e.g., the pads) can be formed from or formed on the outermost conductive layer 906, for example, in the same lamination manufacturing process for the winding board. Furthermore, there is also an additional metal foil (e.g., a copper foil) 908 soldered to another conductive layer of the winding board, and the metal foil 908 may also function like the windings.

In operation, the conductive layer 902 of the main board and the conductive layer 906 of the winding board are configured to have the same voltage, and both of the conductive layer 902 and the conductive layer 906 are configured to be the primary windings or the secondary windings, in order to cooperate with each other.

As a result, when the configuration shown in FIG. 9 is applied in a converter, the coupling of the primary windings with the secondary windings can be improved, the AC coefficient becomes smaller, and the power loss decreases as well.

Notably, each of the conductive layers of the main board and the winding board can be implemented by the primary winding or the secondary winding, and also can be implemented by the combination of the primary winding and the secondary winding; in other words, persons of ordinary skill in the relevant art will recognize that the number and the type of the windings for a single conductive layer can be modified according to practical needs, and thus FIG. 7, FIG. 8 and FIG. 9 are merely illustrative and not limiting of the present disclosure.

Another aspect of the present disclosure is related to a method for manufacturing a converter including a main board, a winding board and a core. Other well-known components in the converter are not shown or described in detail in the method in order to avoid obscuring features and aspects of various embodiments of the present disclosure. In one embodiment, the core can be assembled to the winding board to be a magnetic component such as a transformer, an inductor, or the other type of electromagnetic element, and the main board may be a converter circuit board.

In practice, the main board is a converter printed circuit board (PCB), the winding board is a winding printed circuit board (PCB) (or named PCB winding), and each of the main board and the winding board can be fabricated using well-known circuit lamination techniques.

For convenience and clarity of description, the method for manufacturing the converter is described below in conjunction with the embodiment shown in FIG. 1 or FIG. 4; however, persons of ordinary skill in the relevant art will recognize that the method is applicable to any type of the converter including the main board, the winding board and the core, and thus the method is not limited to the embodiment shown in FIG. 1 or FIG. 4.

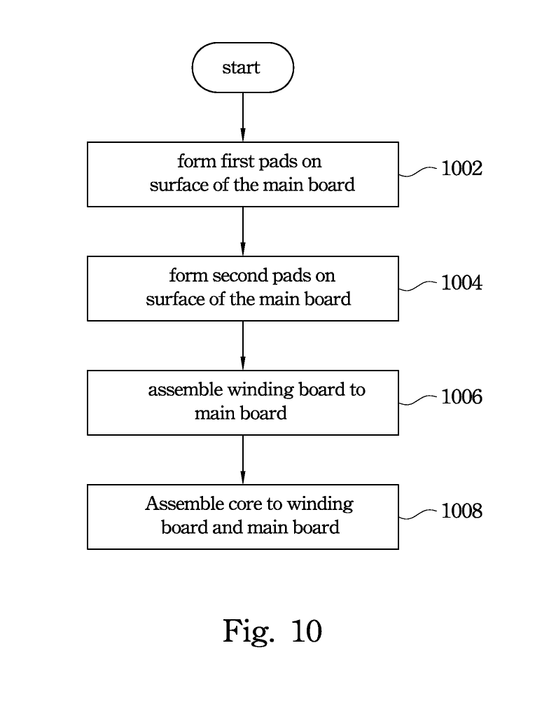

FIG. 10 is a flow chart of a method for manufacturing a converter according to one embodiment of the present disclosure, and the method is described below. First, a plurality of first pads (e.g., the first connecting members 202 shown in FIG. 3) are formed on a surface of the main board (e.g., the main board 110 shown in FIG. 1) (Step 1002). Then, a plurality of second pads (e.g., the second connecting members 204 shown in FIG. 2) are formed on a surface of the winding board (e.g., the winding board 122 shown in FIG. 1) (Step 1004). Thereafter, the winding board is assembled to the main board, and the second pads are soldered to the first pads, respectively (Step 1006). Afterward, the core (e.g., the core 125 shown in FIG. 1) is assembled to the winding board and the main board (Step 1008).

In one embodiment, the winding board further includes a first hollow portion (e.g., the first hollow portion 206 shown in FIG. 2), and the step of assembling the core to the winding board and the main board, i.e., Step 1008, further includes passing the core through the first hollow portion of the winding board.

In another embodiment, the winding board further includes a first hollow portion (e.g., the first hollow portion 206 shown in FIG. 2), the main board further includes a second hollow portion (e.g., the second hollow portion 408 shown in FIG. 6), and the step of assembling the core to the winding board and the main board, i.e., Step 1008, further includes passing the core through the first hollow portion of the winding board and the second hollow portion of the main board.

In practice, each of the first pads formed on the surface of the main board and the second pads formed on the surface of the winding board can be a metal foil, which may be a copper foil, an aluminum foil, a gold foil, a silver foil, a tin foil, a nickel foil, or the combination thereof.

In the embodiments mentioned above, each of the first pads can be formed from one or more conductive layers patterned on the surface of the main board, and each of the second pads can be formed from one or more conductive layers patterned on the surface of the winding board.

In the embodiments mentioned above, the main board may further include a plurality of first conductive layers, the winding board may further include a plurality of second conductive layers, in which the first pads are patterned from an outermost one of the first conductive layers, and the second pads are patterned from an outermost one of the second conductive layers.

Notably, the steps are not necessarily recited in the sequence in which the steps are performed. That is, the sequence of the steps is interchangeable, and all or part of the steps may be simultaneously, partially simultaneously, or sequentially performed.

As is understood by a person skilled in the art, the foregoing embodiments of the present disclosure are illustrative of the present disclosure rather than limiting of the present disclosure. It is intended to cover various modifications and similar arrangements included within the spirit and scope of the appended claims, the scope of which should be accorded with the broadest interpretation so as to encompass all such modifications and similar structures.

What is claimed is:

1. A converter comprising:
a main board;
at least one first connecting member defined on a surface of the main board; and
a magnetic component configured to be assembled with the main board, the magnetic component comprising:
a winding board;
at least one second connecting member defined on a surface of the winding board, the second connecting member configured to be in electrical contact with the first connecting member; and
a core configured to be assembled with the winding board.

2. The converter as claimed in claim 1, wherein the first connecting member is formed from one or more conductive layers patterned on the surface of the main board, and the second connecting member is formed from one or more conductive layers patterned on the surface of the winding board.

3. The converter as claimed in claim 1, wherein the main board further comprises a plurality of first conductive layers, the winding board further comprises a plurality of second conductive layers, the first connecting member is formed from an outermost one of the first conductive layers, and the second connecting member is formed from an outermost one of the second conductive layers.

4. The converter as claimed in claim 3, wherein each of the first conductive layers and the second conductive layers is formed by at least one primary winding, at least one secondary winding, or the combination thereof.

5. The converter as claimed in claim 1, wherein each of the first connecting member and the second connecting member is a pad.

6. The converter as claimed in claim 4, wherein the pad is a metal foil.

7. The converter as claimed in claim 1, wherein the winding board further comprises a first hollow portion for the core to pass through.

8. The converter as claimed in claim 1, wherein the winding board further comprises a first hollow portion for the core to pass through, and the main board further comprises a second hollow portion for the core to pass through.

9. The converter as claimed in claim 1, wherein the first connecting member and the second connecting member are configured to have a same voltage.

10. The converter as claimed in claim 1, wherein the second connecting member is soldered to the first connecting member by solder paste when the winding board is assembled with the main board.

11. A converter comprising:
a converter circuit board;
a plurality of first pads formed on a surface of the converter circuit board;
a winding board comprising a first hollow portion;
a plurality of second pads formed on a surface of the winding board, the second pads configured to be soldered to the first pads, respectively; and
a core configured to pass through the first hollow portion of the winding board.

12. The converter as claimed in claim 11, wherein the converter circuit board further comprises a plurality of first conductive layers, the winding board further comprises a plurality of second conductive layers, the first pads are patterned from an outermost one of the first conductive layers, and the second pads are patterned from an outermost one of the second conductive layers.

13. The converter as claimed in claim 12, wherein each of the first conductive layers and the second conductive layers is formed by at least one primary winding, at least one secondary winding, or the combination thereof.

14. The converter as claimed in claim 11, wherein each of the first pads is formed from one or more conductive layers patterned on the surface of the converter circuit board, and each of the second pads is formed from one or more conductive layers patterned on the surface of the winding board.

15. The converter as claimed in claim 11, wherein each of the first pads and the second pads is a metal foil.

16. The converter as claimed in claim 11, wherein the converter circuit board further comprises a second hollow portion for the core to pass through.

17. A method for manufacturing a converter, the converter comprising a main board, a winding board and a core, the method comprising:
forming a plurality of first pads on a surface of the main board;
forming a plurality of second pads on a surface of the winding board;
assembling the winding board to the main board, and soldering the second pads to the first pads, respectively; and
assembling the core to the winding board and the main board.

18. The method as claimed in claim 17, wherein the winding board further comprises a first hollow portion, and the step of assembling the core to the winding board and the main board further comprises:
passing the core through the first hollow portion of the winding board.

19. The method as claimed in claim 17, wherein the winding board further comprises a first hollow portion, the main board further comprises a second hollow portion, and the step of assembling the core to the winding board and the main board further comprises:
passing the core through the first hollow portion of the winding board and the second hollow portion of the main board.

20. The method as claimed in claim 17, wherein each of the first pads is formed from one or more conductive layers patterned on the surface of the main board, and each of the second pads is formed from one or more conductive layers patterned on the surface of the winding board.

21. The method as claimed in claim 17, wherein the main board further comprises a plurality of first conductive layers, the winding board further comprises a plurality of second conductive layers, the first pads are patterned from an outermost one of the first conductive layers, and the second pads are patterned from an outermost one of the second conductive layers.

22. The method as claimed in claim 17, wherein each of the first pads and the second pads is a metal foil.
